(19) United States
(12) Patent Application Publication
(10) Pub. No.: US 2008/0315284 A1
(43) Pub. Date: Dec. 25, 2008

(54) Flash memory structure and method of making the same

(76) Inventors: Ching-Nan Hsiao, Kaohsiung County (TW); Chung-Lin Huang, Tao-Yuan City (TW); Chen-Yu Tsai, Taipei County (TW); Chung-Yuan Lee, Tao-Yuan City (TW)

Correspondence Address: NORTH AMERICA INTELLECTUAL PROPERTY CORPORATION, P.O. BOX 506, MERRIFIELD, VA, 22116, US

(21) Appl. No.: 11/953,886

(22) Filed: Dec. 11, 2007

(30) Foreign Application Priority Data
Jun. 21, 2007 (TW) 096122312

(51) Int. Cl. H01L 29/00; H01L 21/336

(52) U.S. Cl. 257/316; 438/261; 257/E29.3; 257/E21.422

(57) ABSTRACT

A flash memory cell includes a substrate, a T-shaped control gate disposed above the substrate, a floating gate embedded in a lower recess of the T-shaped control gate, a dielectric layer between the T-shaped control gate and the floating gate; a cap layer above the T-shaped control gate, a control gate oxide between the T-shaped control gate and the substrate, a floating gate oxide between the floating gate and the substrate, a liner covering the cap layer and the floating gate, and a source/drain region adjacent to the floating gate. The floating gate has a vertical wall surface that is coplanar with one side of the dielectric layer.

### BACKGROUND OF THE INVENTION

1. Field of the Invention

The present invention relates generally to the field of memory devices and fabrication method thereof. More particularly, the present invention relates to a flash memory cell structure with increased coupling ratio and method of making the same.

2. Description of the Prior Art

A flash memory is a non-volatile computer memory that can be electrically erased and reprogrammed. It is a technology that is primarily used in, for example, memory cards or USB flash drives, which are used for general storage and transfer of data between processors and other digital products. Presently, scaling down of flash memory cells has been considered critical in continuing the trend toward high device density.

FIG. 1 is a schematic cross-sectional view showing a conventional two-bit flash memory cell unit. The conventional two-bit flash memory cell unit comprises a substrate 10, a composite dielectric layer 12 consisting of a silicon oxide layer 14, a silicon nitride layer 16 and a silicon oxide layer 18. Basically, electrical charge is stored at two distal ends of the silicon nitride layer 16 as indicated by numerals 16a and 16b. A control gate 20 is provided atop the composite dielectric layer 12.

The above-described flash memory cell unit is also known as nitride read-only-memory (NROM). One major drawback of the above-described flash memory cell unit is its poor data retention capability. Besides, as the size of the cells shrink, short channel effect and alignment become major problems to the manufacturers.

Accordingly, a need exists in this industry to reduce short channel effect in a flash memory cell having smaller unit cell size, while maintaining reliable cell operation and performance.

### SUMMARY OF THE INVENTION

It is one objective of the present invention to provide an improved flash memory cell structure and fabrication method thereof. The present invention method is characterized in that the floating gate is formed prior to the formation of the control gate. By doing this, the coupling ratio between the floating gate and the control gate is increased. The present invention memory cell structure and its fabrication method are provided to reduce the alignment difficulty during the fabrication of the memory cell. Further, the present invention aims to solve the short channel effect.

From one aspect of the present invention, a flash memory cell structure is provided. The flash memory cell structure comprises a substrate; a T-shaped control gate on the substrate; a floating gate embedded in a lower recess of the T-shaped control gate; a dielectric layer between the T-shaped control gate and the floating gate; a cap layer directly on the T-shaped control gate; a control gate oxide layer between the T-shaped control gate and the substrate; a floating gate oxide layer between the floating gate and the substrate; a liner layer covering the cap layer and a vertical surface of the floating gate; and a source/drain doping region in the substrate next to the floating gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional view showing a conventional two-bit flash memory cell unit.

FIG. 2 is a schematic layout top plan view of an array of flash memory cells in accordance with the preferred embodiment of this invention.

FIG. 3 is a schematic, cross-sectional view illustrating two adjacent flash memory cells taken along line 3-3 of FIG. 2.

FIG. 4 is a cross-sectional view taken along line 4-4 of FIG. 2.

FIGS. 5-12 are schematic partially cross sectional views showing the fabrication steps for making the flash memory cell units as depicted in FIG. 3 according to this invention.

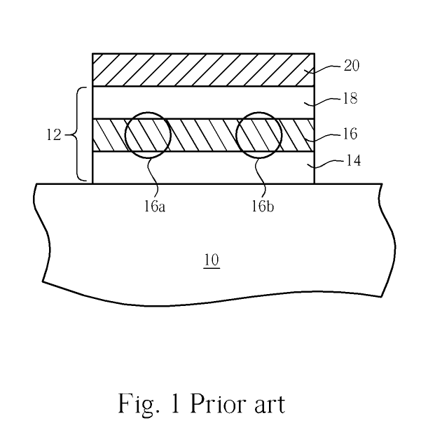

### DETAILED DESCRIPTION

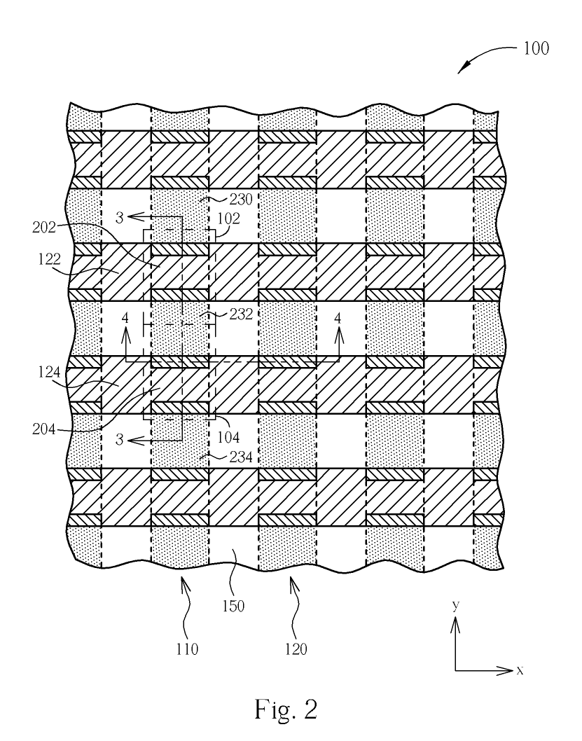

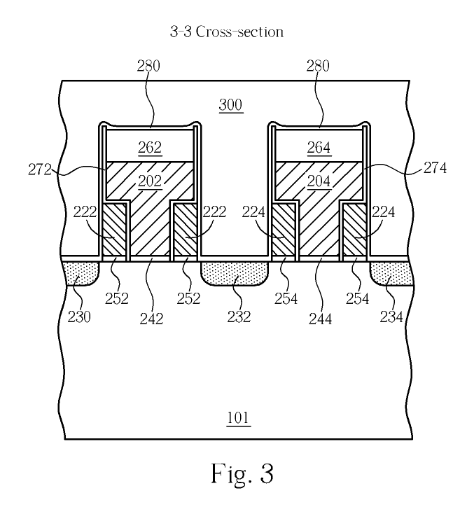

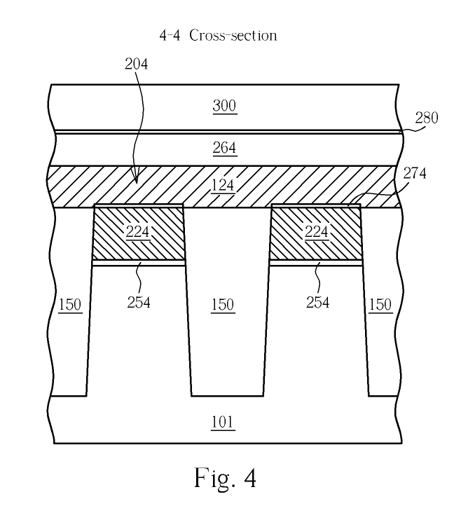

With reference to FIGS. 2 to 4, wherein FIG. 2 is a schematic layout view of an array of flash memory cells in accordance with the preferred embodiment of this invention, FIG. 3 is a schematic, cross-sectional view illustrating two adjacent flash memory cell units taken along line 3-3 of FIG. 2, and FIG. 4 is a cross-sectional diagram taken along line 4-4 of FIG. 2.

As shown in FIG. 2, the flash memory array 100 comprises a flash memory cell unit 102 and a flash memory cell unit 104 next to the flash memory cell unit 102. The flash memory cell unit 102 and the flash memory cell unit 104 are serially connected to one another along y-axis of a NAND memory block 110 and are part of a NAND memory block 110. The NAND memory block 110 may be a 16-bit memory block or 32-bit memory block, but not limited thereto.

The flash memory array 100 further comprises word line 122 and word line 124 disposed along the x-axis of the memory block 110. The word line 122 and word line 124 are electrically connected with a T-shaped control gate 202 of the flash memory cell unit 102 and a T-shaped control gate 204 of the flash memory cell unit 104, respectively. The NAND memory block 110 is insulated from the neighboring NAND memory block 120 with a shallow trench isolation (STI) structure 150.

The flash memory cell unit 102 comprises source/drain doping regions 230 and 232, which are implanted into the substrate at two sides of the T-shaped control gate 202. The flash memory cell unit 104 comprises source/drain doping regions 232 and 234, which are at two sides of the T-shaped control gate 204. The source/drain doping region 232 is shared by the flash memory cell units 102 and 104.

As shown in FIG. 3, the flash memory cell unit 102 comprises a T-shaped control gate 202, floating gates 222, dielectric layer 272, cap layer 262, control gate oxide layer 242, floating gate oxide layer 252, liner layer 280 and source/drain doping regions 230 and 232.

One distinct feature of the present invention is that the floating gates 222 are disposed and inlaid into respective lower recessed areas at the foot of the T-shaped control gate 202. The floating gate 222 has one vertical surface that is coplanar with the surface of the dielectric layer 272, which constitute a vertical sidewall surface.

The floating gate 222 is embedded in the lower recessed area of the T-shaped control gate 202. The dielectric layer 272 is disposed between the T-shaped control gate 202 and the floating gate 222. The cap layer 262 is disposed directly above the T-shaped control gate 202. The control gate oxide layer 242 is located between the T-shaped control gate 202 and the substrate 101. The floating gate oxide layer 252 is disposed between the floating gate 222 and the substrate 101. The cap layer 262 and the vertical surface of the floating gate 222 are covered by the liner layer 280. The source/drain doping region 230 and 232 are disposed in the substrate 101 next to the floating gate 222.

As shown in FIGS. 3 and 4, the flash memory cell unit 104 comprises a T-shaped control gate 204, floating gates 224, dielectric layer 274, cap layer 264, control gate oxide layer 244, floating gate oxide layer 254, liner layer 280 and source/drain doping regions 232 and 234. The liner layer 280 is covered by a dielectric layer 300.

Likewise, the floating gate 224 is embedded in the lower recessed area of the T-shaped control gate 204. The dielectric layer 274 is disposed between the T-shaped control gate 204 and the floating gate 224. The cap layer 264 is disposed directly above the T-shaped control gate 204. The control gate oxide layer 244 is located between the T-shaped control gate 204 and the substrate 101. The floating gate oxide layer 254 is positioned between the floating gate 224 and the substrate 101. The cap layer 264 and the vertical surface of the floating gate 224 are covered by the liner layer 280. The source/drain doping region 232 and 234 are disposed in the substrate 101 next to the floating gate 224.

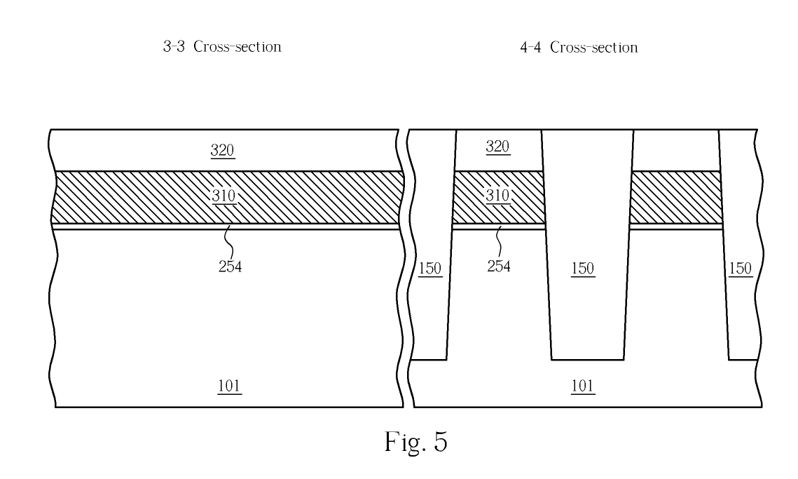

Reference is now made to the embodiment illustrated in FIGS. 5-12, wherein the various processing steps employed in fabricating the inventive flash memory cell unit of FIG. 3 are shown. For the sake of clarity, the cross-sectional views of FIG. 2 are used to demonstrate the processing steps through FIGS. 5-12.

The present invention method features that the floating gates of the flash memory cell unit are formed prior to the formation of the control gate. The resultant T-shaped control gate and the embedded floating gates increase the coupling ratio thereof.

First, as shown in FIG. 5, a substrate 101 is provided. The substrate 101 may be a semiconductor substrate, such as silicon substrate, SOI substrate or SiGe substrate, but not limited thereto. A dielectric layer is formed on the substrate 101. For example, the dielectric layer may be a silicon oxide layer formed by oxidation processes and the dielectric layer acts as a floating gate oxide layer 254. Subsequently, a conductive layer 310 is formed on the floating gate oxide layer 254. For example, the conductive layer 310 may be a polysilicon layer or doped polysilicon layer formed by conventional chemical vapor deposition (CVD) processes. A pad layer 320 is then formed on the conductive layer 310. For example, the pad layer 320 may be a silicon oxide layer formed by conventional CVD processes.

A patterning process is carried out to define the active area and STI structure 150. The patterning process includes a lithographic process and an etching process. The formation of the STI structure 150 may include the steps of: etching STI trenches into the substrate, filling the STI trenches with insulating material, such as silicon oxide dielectric layer deposited by conventional CVD methods or HDPCVD methods, then using the pad layer 320 as a polish stop layer, performing a planarizing process such as chemical mechanical polishing (CMP) to remove the extra silicon oxide dielectric layer outside the STI trenches.

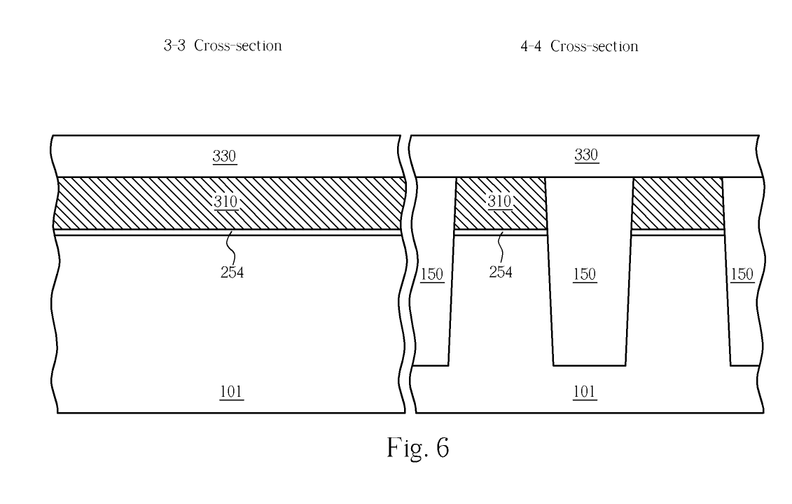

As shown in FIG. 6, the pad layer 320 is then removed by any suitable methods, such as wet etching processes. Another CMP process is carried out to polish the protruding STI structure 150 after removing the pad layer 320, thereby forming a planar surface. After the CMP process, a CVD process is performed to deposit a mask layer 330, such as a silicon oxide layer on the planar surface of the susbtrate.

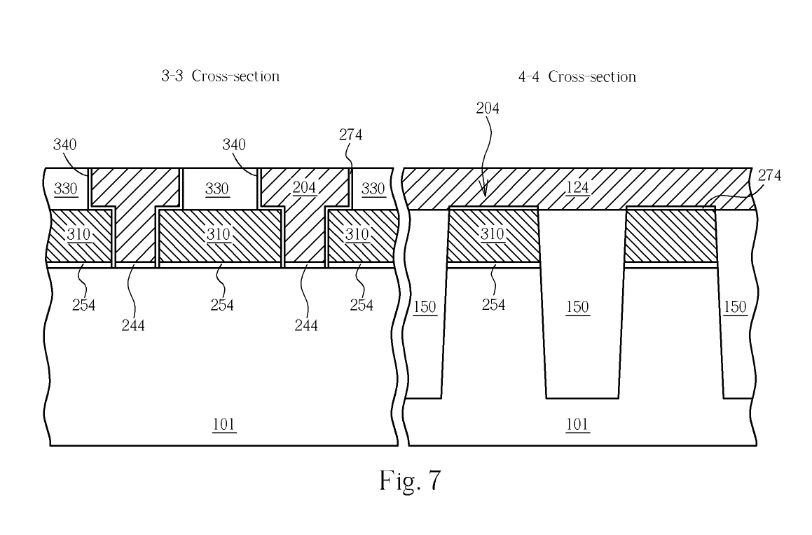

As shown in FIG. 7, a patterning process including a lithographic process is then performed to form a photo resist pattern (not shown) on the mask layer 330 to define the position and pattern of word lines. Thereafter, a dry etching process using etchant such as CF4 is performed to remove the mask layer 330 and the conductive layer 310, thereby transferring the photo resist pattern into the mask layer 330. A pull back process is then performed to trim the mask layer 330, for example, wet etching process using HF as an etchant, thereby laterally remove a thickness of the mask layer 330 and exposing a portion of the underlying conductive layer 310. After the pull back process, a T-shaped recess 340 is formed in the mask layer 330 and the conductive layer 310.

A dielectric layer 274, such as an oxide, oxide-nitride (ON), oxide-nitride-oxide (ONO) layer or the like, is formed on the interior surface of the T-shaped recess 340. The dielectric layer 274 may be formed by oxidation or CVD processes in combination with dry etching processes. A dielectric layer such as silicon oxide layer is then formed at the bottom of the T-shaped recess 340. The dielectric layer is control gate oxide layer 244 and may be formed by oxidation processes. A conductive layer is deposited to fill the T-shaped recess 340. Preferably, the conductive layer is a polysilicon layer formed by conventional CVD processes. Subsequently, the excess conductive layer outside the T-shaped recess 340 is removed by CMP to form a T-shaped conductive structure inlaid in the T-shaped recess 340 that acts as the T-shaped control gate 204 of the flash memory cell unit 104. The word line 124 is formed concurrently with the T-shaped control gate 204 after CMP.

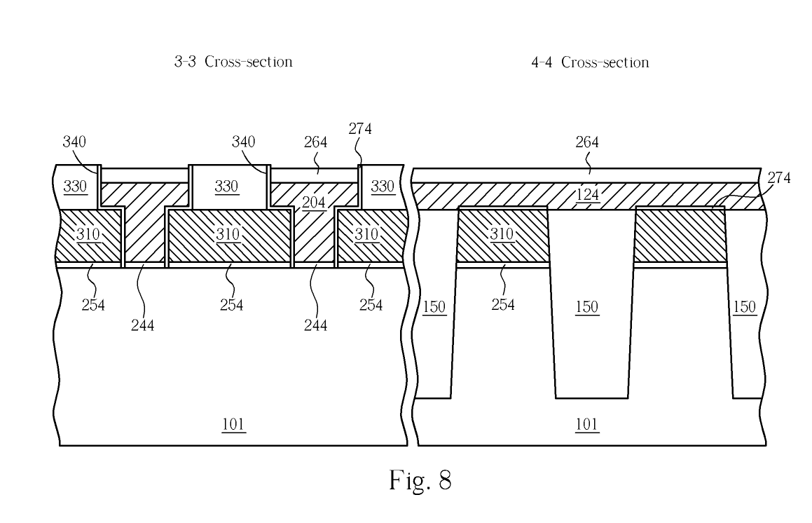

As shown in FIG. 8, the T-shaped control gate 204 and the word line 124 are concurrently etched using dry etching processes, for example, dry etching employing etchant including but not limited to Cl₂ or F. After the dry etching, the top surface of the T-shaped control gate 204 is lower than the top surface of the mask layer 330, thereby forming a recessed area. An insulating layer, such as a silicon nitride layer (not shown) is blanket deposited onto the substrate using conventional CVD processes. The insulating layer is then polished using CMP to form the cap layer 264 directly on the T-shaped control gate 204 and also on the word line 124.

Subsequently, could be selectively etching away a pre-selected thickness of the cap layer 264 using dry etching process, such as CF₄ dry etching such that the top surface of the cap layer 264 is lower than the top surface of the mask layer 330. The major purpose of this step is to ensure that residual silicon nitride is completely removed from the surface of the mask layer 330 and to facilitate the removal of the mask layer 330.

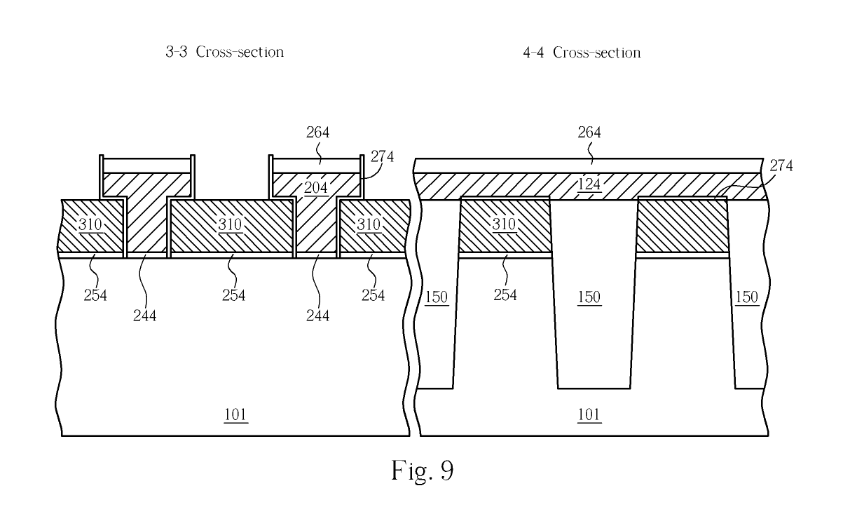

As shown in FIG. 9, a selective etching process, such as a wet etching process of using HF as an etchant is performed to removed the mask layer 330 so that expose a portion of the conductive layer 310. The T-shaped control gate 204 is protected by the cap layer 264 and the dielectric layer 274 during the removal of the mask layer 330.

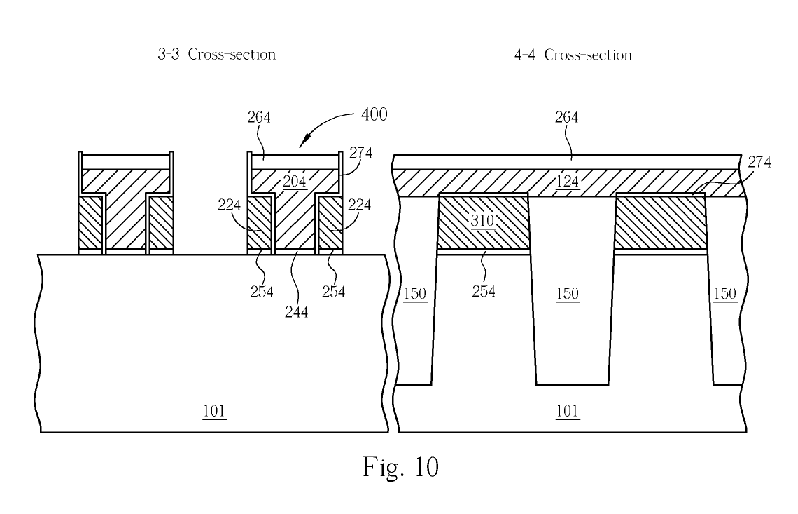

As shown in FIG. 10, utilizing the cap layer 264 and the dielectric layer 274 as an etching mask, a dry etching process employing etchant, such as Cl2 or F is performed to remove a portion of the conductive layer 310 and the floating gate oxide layer 254, thereby forming the floating gate 224 and the gate structure 400 of the flash memory cell unit in a self-aligned fashion.

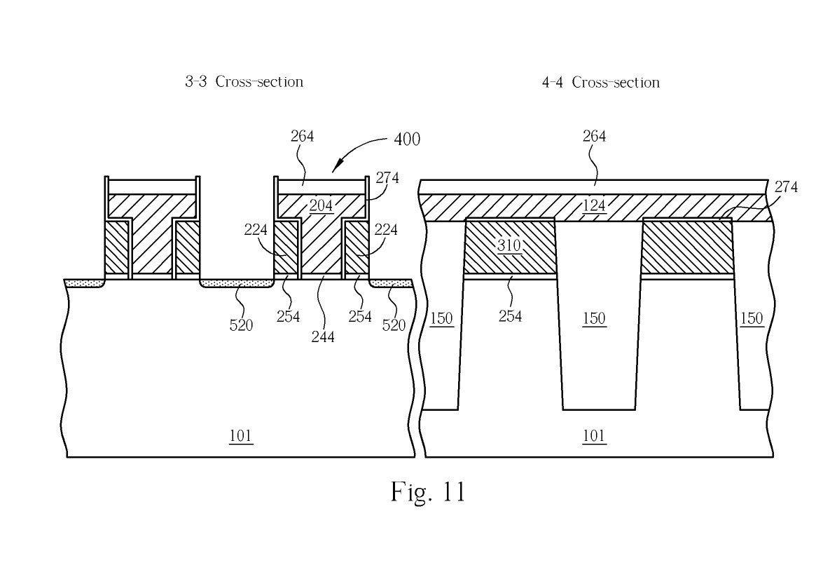

As shown in FIG. 11, utilizing the cap layer 264 and the dielectric layer 274 as a mask, an ion implantation process is performed to implant N or P type dopants into the substrate 101 next to the floating gate 224, thereby forming lightly doped drain (LDD) regions 520. However, this step may be omitted in another embodiment.

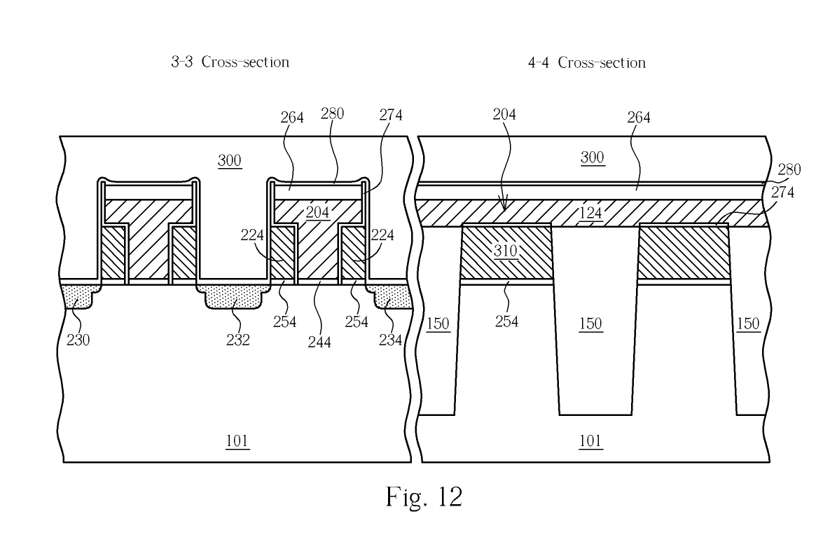

As shown in FIG. 12, a liner layer 280 such as silicon nitride is blanket deposited on the substrate 101 and covers the gate structure 400. Preferably, the liner layer 280 has a thickness of about 30-300 angstroms, but not limited thereto. Thereafter, an ion implantation process is carried out to implant N or P type dopants into the substrate 101 adjacent to the floating gate 224, thereby forming source/drain doping regions 230, 232 and 234. Finally, a dielectric layer 300 is deposited on the liner layer 280.

Those skilled in the art will readily observe that numerous modifications and alterations of the device and method may be made while retaining the teachings of the invention.

What is claimed is:

1. A flash memory cell unit comprising:
a substrate;
a T-shaped control gate formed on the substrate;
a floating gate embedded in a lower recess of the T-shaped control gate;
a dielectric layer located between the T-shaped control gate and the floating gate;
a cap layer disposed directly on the T-shaped control gate;
a control gate oxide layer disposed between the T-shaped control gate and the substrate;
a floating gate oxide layer positioned between the floating gate and the substrate;
a liner layer covering the cap layer and a vertical surface of the floating gate, wherein the vertical surface of the floating gate is coplanar with a surface of the dielectric layer; and
a source/drain doping region in the substrate next to the floating gate.

2. The flash memory cell unit according to claim 1, wherein the dielectric layer and the cap layer encapsulate the T-shaped control gate.

3. The flash memory cell unit according to claim 1, wherein the dielectric layer comprises oxide-nitride (ON) layer or oxide-nitride-oxide (ONO) layer.

4. The flash memory cell unit according to claim 1, wherein the cap layer comprises silicon nitride layer.

5. The flash memory cell unit according to claim 1, wherein the T-shaped control gate comprises polysilicon layer.

6. The flash memory cell unit according to claim 1, wherein the floating gate comprises polysilicon layer.

7. The flash memory cell unit according to claim 1, wherein the liner layer comprises silicon nitride layer.

8. The flash memory cell unit according to claim 1, further comprising a lightly doped drain (LDD) region.

9. A method for forming a T-shaped conductive structure of a memory, comprising:
providing a substrate having thereon a floating gate oxide layer and a first conductive layer;
depositing a mask layer over the substrate;
forming a T-shaped recess in the mask layer and the first conductive layer;
forming a first dielectric layer on an interior surface of the T-shaped recess;
depositing a second conductive layer to fill the T-shaped recess, thereby forming a T-shaped control gate;
recessing a top surface of the T-shaped control gate such that the top surface of the T-shaped control gate is lower than that of the mask layer, thereby defining a recessed area;
forming a cap layer in the recessed area;
removing the mask layer so that expose a portion of the first conductive layer; and
etching the portion of the first conductive layer and the floating gate oxide layer, thereby forming a floating gate in a self-aligned fashion.

10. The method according to claim 9, after formation of the floating gate, further comprising the steps of:
using the cap layer and the first dielectric layer as a mask, performing an ion implantation process to implant N or P type dopants into the substrate next to the floating gate, thereby forming lightly doped drain (LDD) regions.

11. The method according to claim 9, after formation of the floating gate, further comprising the steps of:
depositing a liner layer on the substrate, wherein the liner layer covers the cap layer and the floating gate; and
performing an ion implantation process to implant N or P type dopants into the substrate next to the floating gate, thereby forming source/drain doping regions.

12. The method according to claim 11, wherein the liner layer has a thickness of 30-300 angstroms.

13. The method according to claim 9, wherein the first dielectric layer comprises oxide-nitride (ON) layer or oxide-nitride-oxide (ONO) layer.

14. The method according to claim 9, wherein the second dielectric layer comprises silicon oxide layer.

15. The method according to claim 9, wherein the etching back the T-shaped control gate is dry etching.

16. The method according to claim 9, wherein after forming the first dielectric layer on interior surface of the T-shaped recess, the method further comprises a step of: forming a second dielectric layer at bottom of the T-shaped recess.
